(19) United States
(12) Patent Application Publication
(10) Pub. No.: US 2007/0257273 A1
(43) Pub. Date: Nov. 8, 2007

(54) Novel optical cover for optical chip

(75) Inventor: Jonathan Gorrell, Gainesville, FL (US)

Correspondence Address: DAVIDSON BERQUIST JACKSON & GOWDEY LLP, 4300 WILSON BLVD., 7TH FLOOR, ARLINGTON, VA, 22203, US

(73) Assignee: Virgin Island Microsystems, Inc., St. Thomas, VI (US)

(21) Appl. No.: 11/418,079

(22) Filed: May 5, 2006

(51) Int. Cl. H01L 33/00

(52) U.S. Cl. 257/98

(57) ABSTRACT

A cover for use together with a transmitter of an encoded light or EMR beam for intercepting and re-directing the beam away from the transmitter toward a receiver, an optical device or another solid state device whereby data encoded on the encoded light or EMR beam can be transmitted out of the transmitter to a receiver and the data encoded thereon can be used or retransmitted.

### CROSS-REFERENCE TO RELATED APPLICATIONS

The present invention is related to the following co-pending U.S. Patent applications which are all commonly owned with the present application, the entire contents of each of which are incorporated herein by reference:
1. U.S. patent application Ser. No. 11/238,991, entitled “Ultra-Small Resonating Charged Particle Beam Modulator,” filed Sep. 30, 2005;
2. U.S. patent application Ser. No. 10/917,511, entitled “Patterning Thin Metal Film by Dry Reactive Ion Etching,” filed on Aug. 13, 2004;
3. U.S. application Ser. No. 11/203,407, entitled “Method Of Patterning Ultra-Small Structures,” filed on Aug. 15, 2005;
4. U.S. application Ser. No. 11/243,476, entitled “Structures And Methods For Coupling Energy From An Electromagnetic Wave,” filed on Oct. 5, 2005;
5. U.S. application Ser. No. 11/243,477, entitled “Electron beam induced resonance,” filed on Oct. 5, 2005;
6. U.S. application Ser. No. 11/325,448, entitled “Selectable Frequency Light Emitter from Single Metal Layer,” filed Jan. 5, 2006;
7. U.S. application Ser. No. 11/325,432, entitled, “Matrix Array Display,” filed Jan. 5, 2006;
8. U.S. application Ser. No. 11/302,471, entitled “Coupled Nano-Resonating Energy Emitting Structures,” filed Dec. 14, 2005;
9. U.S. application Ser. No. 11/325,571, entitled “Switching Micro-resonant Structures by Modulating a Beam of Charged Particles,” filed Jan. 5, 2006;
10. U.S. application Ser. No. 11/325,534, entitled “Switching Microresonant Structures Using at Least One Director,” filed Jan. 5, 2006;
11. U.S. application Ser. No. 11/350,812, entitled “Conductive Polymers for Electroplating,” filed Feb. 10, 2006;
12. U.S. application Ser. No. 11/349,963, entitled “Method and Structure for Coupling Two Microcircuits,” filed Feb. 9, 2006;
13. U.S. application Ser. No. 11/353,208, entitled “Electron Beam Induced Resonance,” filed Feb. 14, 2006;
14. U.S. application Ser. No.11/______, entitled “Reflecting Filtering Cover” [Atty. Docket 2549-0078], filed on even date herewith.

### COPYRIGHT NOTICE

A portion of the disclosure of this patent document contains material which is subject to copyright or mask work protection. The copyright or mask work owner has no objection to the facsimile reproduction by anyone of the patent document or the patent disclosure, as it appears in the Patent and Trademark Office patent file or records, but otherwise reserves all copyright or mask work rights whatsoever.

### FIELD OF THE DISCLOSURE

This relates in general to reflectors as a part of chip production, or the production of other forms of solid state devices, and specifically to covers or reflective surfaces on one side of a chip.

### INTRODUCTION

In the related applications described above, micro- and nano-resonant structures, referenced as ultra small resonant structures, are described that react in now-predictable manners when an electron beam is passed in their proximity. We have seen, for example, that the very small structures described in those applications allow energy of the electron beam to be converted into the energy of electromagnetic radiation (light), or other EMR radiation, when the electron beam passes nearby. When the electron beam passes near the ultra small resonant structures, it excites synchronized oscillations of the electrons in the ultra small resonant structures (surface plasmons). As often repeated as the many electrons in a beam pass, these surface plasmons result in reemission of detectable photons as electromagnetic radiation (EMR).

The EMR can be modulated to encode data from a data source. The encoded EMR can then transport the data at an extremely fast data rate. Further, using resonant structures of the types described in the related applications, the transmitter can be built into a chip and used to transmit the data within a microcircuit (intra-chip) or between one or more microcircuits of one or more chips. A number of methods of encoding such data can be envisioned and is not delimiting of the inventions described herein.

We herein disclose methods and structures for sending and receiving the encoded EMR so that the data in the encoded EMR can be transmitted out of a chip, transmitted between various locations on a chip and be used at the receiving end, whether on the chip or at another location.

### BRIEF DESCRIPTION OF THE DRAWINGS

FIG. 1A is a schematic view of an embodiment of the present invention;

FIG. 1B is a schematic view of another embodiment of the present invention; and

FIG. 2 is another alternative embodiment of the present invention;

### THE PRESENTLY PREFERRED EXEMPLARY EMBODIMENTS

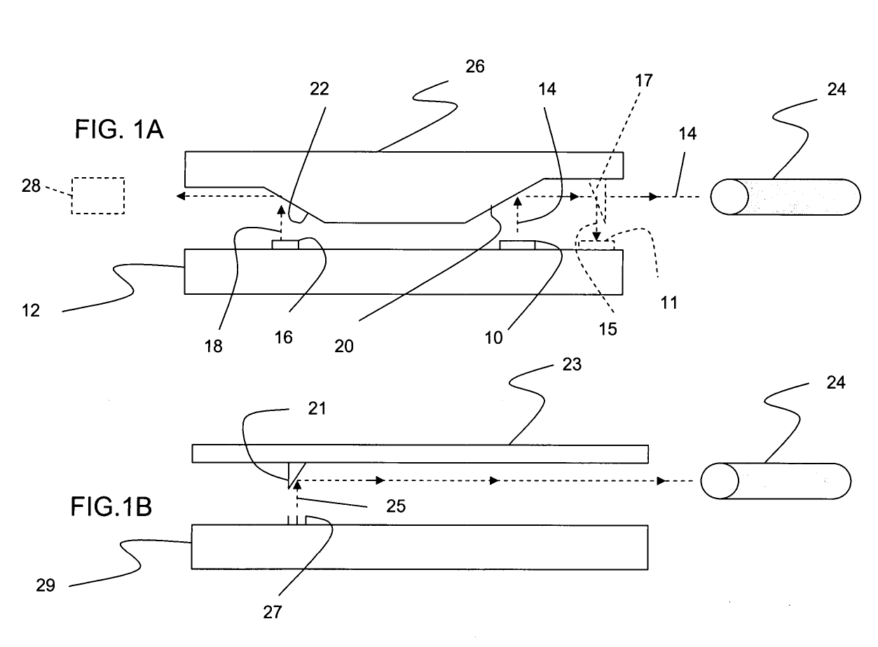

With reference to FIG. 1A, a transmitter 10 can include an ultra-small resonant structure, such as any one described in U.S. patent application Ser. Nos. 11/238,991; 11/243,476; 11/243,477; 11/325,448; 11/325,432; 11/302,471; 11/325,571; 11/325,534; 11/349,963; and/or 11/353,208(each of which is identified more particularly above). The resonant structures comprising the transmitter can be manufactured in accordance with any of U.S. application Ser. Nos. 10/917,511; 11/350,812; or 11/203,407 (each of which is identified more particularly above) or in other ways. Their sizes and dimensions can be selected in accordance with the principles described in those applications and, for the sake of brevity, will not be repeated herein. The contents of the applications described above are assumed to be known to the reader.

Although less advantageous than the ultra-small resonant structures identified in the applications described above, alternatively the transmitter 10 can also comprise any macroscopic or microscopic light emitter, and can include even prior art LEDs, semiconductors or other light-emitting devices. The ultra-small structures are employed in a vacuum environment. Methods of evacuating the environment where the exciting and emitted encoded EMR beams move can be selected from known evacuation methods.

The transmitter 10 mounted to a chip or substrate 12, can be operated in association with a data source (not shown as it is described in one or more of the above referenced applications and will not be repeated herein), which may be part of the transmitter or may be separated from the transmitter. For purposes of this disclosure, the kind of data transmitted, the kind of EMR produced, and the kind of structure producing the EMR are not delimiting. It matters only that in some way data are encoded, for example, into an EMR beam referenced at 14 which can be directed to a reflector 20 formed in the bottom surface of a cover structure 26, and be re-directed out of the chip or off the substrate 12 to, for example, a fiber optic receiver 24. Alternatively, another reflector such as that shown in phantom at 17 as being mounted or formed in the cover structure 26, the beam could be re-directed within the chip as shown in phantom at 15 to another receiver, shown in phantom at 11, mounted on another portion of the chip.

Alternatively, this could also include use of a data source that supplies data to, for example, a light encoder 16 that encodes the data into a light beam 18 and transmits that encoded light or an EMR beam 18 to a reflector 22, for example, also be formed into or as part of the bottom surface of cover structure 26. The reflector 22 then re-directs the encoded light or EMR beam 18 off the surface of substrate 12 in an inter-chip direction or, for example, toward another fiber optic device, shown in phantom at 28, or where ever it was desired to direct the encoded light or EMR beam 18 so that it could be received and used. The reflectors 20 and 22 could also be formed as a part of the bottom of another chip mounted above the chip or substrate 12.

However, the reflectors 20, 22 and/or 17 in either configuration are designed to send the EMR beam 14, beam 15, or the encoded light beam 18, respectively, to a suitable receiver, located intra-chip or inter-chip, where the data thereon can be received and used.

FIG. 1B shows an alternative reflective structure in the form of a separately formed structure 21 formed on the bottom surface of a cover structure 23 that will intersect beam 25 emitted by transmitter 27 on a chip 29 and re-direct beam 25 out to an optical receiver 24. Here again, an additional reflector could also be used, as shown in FIG. 1A at 17 to redirect the beam within the chip architecture, so that both inter-chip and intra-chip beam use is possible.

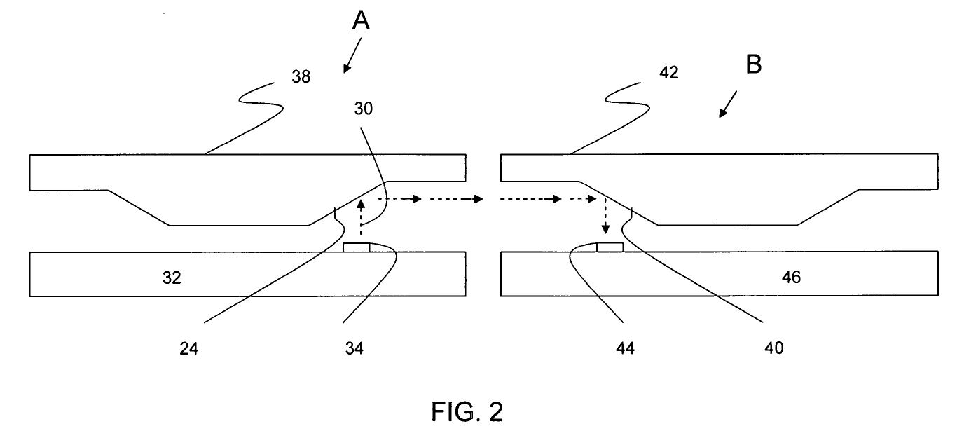

FIG. 2 shows another inter-chip beam reflection embodiment where either an EMR beam or an encoded light beam, generally referenced at 30, has been emitted from the surface of substrate 32 of chip A, specifically from a transmitter 34, and is reflected by surface 36 on the bottom side of cover 38 to a reflector surface 40 on the bottom surface of cover 42 of chip B. The beam 30 will be reflected by the reflector surface 40 downwardly to a receiver 44 on substrate 46 where the data encoded on beam 30 can be used within chip B. It should be understood that instead of using reflective surfaces 36 and 40 they could be replaced by reflective structures as shown at 21 in FIG. 1A, or structures similar thereto formed as needed above the transmitter 34.

What is important with this invention is the ability to position a suitable reflective surface or device above a transmitter of a beam of light or other EMR radiation on which data has been encoded, so that the emitted beam can be re-directed to another location where it can be received an the data encoded thereon or therein can be received and used.

As the term is used herein, the resonant structures are considered ultra-small when they embody at least one dimension that is smaller than the wavelength of visible light.

While certain configurations of structures have been illustrated for the purposes of presenting the basic structures of the present invention, one of ordinary skill in the art will appreciate that other variations are possible which would still fall within the scope of the appended claims. While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. A cover for a chip comprising at least one reflective surface for re-directing an encoded light or EMR beam emitted by an ultra-small resonant structure to another location on or off the chip on which the encoded light or EMR beam has been created.

2. The cover according to claim 1 wherein the cover comprises the bottom of another chip mounted there above.

3. The cover according to claim 1 wherein the transmitter is mounted on the chip.

4. The cover according to claim 1 wherein at least one reflective surface is formed as a separate structure on the bottom of the cover.

5. The cover according to claim 1 wherein a plurality of reflective surfaces are formed on the bottom of the cove for re-directing a plurality of encoded light or EMR beams.

6. The cover according to claim 1 wherein the reflective surface re-directs encoded light or EMR beam onto a receiver mounted on a device in the path of the re-directed beam.

7. The cover according to claim 6 wherein the device comprises a chip.

8. The cover according to claim 1 wherein the at least one reflective surface re-direct the beam toward a receiving device.

9. The cover according to claim 8 wherein the receiving device comprises an optical device.

10. The cover according to claim 8 wherein the receiving device comprises another solid state device.
